(19) United States
(12) Patent Application Publication
(10) Pub. No.: US 2026/0318730 A1
(43) Pub. Date: Oct. 15, 2026

(54) APPARATUS FOR MEASURING THE MASS AND/OR THE CHANGE IN MASS OF AN OBJECT

(71) Applicant: METRYX LTD., Bristol (GB)

(72) Inventors: Sam OWENS, Bristol (GB); Vivek RAMAKRISHNAN, Bristol (GB)

(21) Appl. No.: 19/483,476

(22) PCT Filed: Apr. 16, 2024
(86) PCT No.: PCT/EP2024/060309

§ 371 Date: Nov. 11, 2025

(30) Foreign Application Priority Data
May 22, 2023 (GB) 2307641.7

(51) Int. Cl. G01G 7/02; G01G 21/28; G01G 23/01; G01R 33/02

(52) U.S. Cl. CPC G01G 7/02; G01G 21/28; G01G 23/01; G01R 33/0206

(57) ABSTRACT

Apparatus for measuring the mass and/or the change in mass of an object, comprising: a load cell; and a magnetic field sensor.

### FIELD OF THE INVENTION

The present invention relates to an apparatus for measuring the mass and/or the change in mass of an object and particularly, although not exclusively, to an apparatus for measuring the mass and/or the change in mass of a wafer such as a semiconductor wafer.

### BACKGROUND

Microelectronic devices are fabricated on semiconductor (e.g. silicon) wafers using a variety of techniques, e.g. including deposition techniques and removal techniques. Semiconductor wafers may be further treated in ways that alter their mass, e.g. by cleaning, ion implantation, lithography and the like.

Wafer treatment techniques typically cause a change in mass at or on the surface of the semiconductor wafer. The configuration of the changes to the surface are often vital to the functioning of the device, so it is desirable for quality control purposes to assess wafers during production in order to determine whether they have the correct configuration.

Specialist metrology tools may be used within the production flow so that monitoring is conducted soon after the relevant process of interest and usually before any subsequent processing, i.e. between processing steps.

Measuring the change in mass of a wafer either side of a processing step is an attractive method for implementing product wafer metrology. It is relatively low cost, high speed and can accommodate different wafer circuitry patterns automatically. In addition, it can often provide results of higher accuracy than alternative techniques. The wafer in question is weighed before and after the processing step of interest. The change in mass is then correlated to the performance of the production equipment and/or the desired properties of the wafer.

Typically, a measurement of the weight or mass of a wafer is performed before the processing step on a wafer mass metrology apparatus and then the same apparatus is used to measure the weight or mass of the wafer after the processing step. The measurement results are then used to calculate a change in mass of the wafer caused by the processing step. This change in mass can then be correlated to the performance of the production equipment and/or the desired properties of the wafer.

One key component of a wafer mass metrology apparatus is the load cell. One known type of load cell that can be used to perform such measurements is an electromagnetic force compensation load cell. At its most general, an electromagnetic force compensation load cell uses an electromagnetic force to balance out the weight force of the object. Typically, the weight force of the object is applied to a beam on a first side of a pivot about which the beam can pivot, and the electromagnetic force is applied to the beam on a second side of the pivot so that a moment of force due to the electromagnetic force cancels out a moment of force due to the weight force of the object. In such a situation, the beam does not move, because there is no net moment of force on the beam.

The electromagnetic force that is required to prevent movement of the beam when the weight force is applied to the beam therefore corresponds to, or is indicative of, the weight force of the object. Movement (or lack of movement) of the beam can be detected using a detector, typically an optical detector.

An electromagnetic force compensation load cell includes an electromagnetic force compensation mechanism for generating the electromagnetic force. The electromagnetic force compensation mechanism typically comprises an electromagnetic coil that is attached to the beam, and a magnet that is appropriately positioned close to the electromagnetic coil. The electromagnetic force is generated by applying a current to the electromagnetic coil so that there is a magnetic force between the electromagnetic coil and the magnet. Typically, the magnet is a permanent magnet, which is typically positioned beneath the electromagnetic coil.

The electromagnetic force that is generated by such an electromagnetic force compensation mechanism depends on the current applied to the electromagnetic coil. Therefore, the current that is required to be supplied to the electromagnetic coil to prevent movement of the beam when the weight force is applied to the beam corresponds to, or is indicative of, the weight force of the object. The weight force of the object can therefore be determined by determining the current that is required to be supplied to the electromagnetic coil to prevent movement of the beam when the weight force is applied to the beam.

The load cell may comprise a controller or processor that is configured to multiply a measurement result of the load cell by a predetermined calibration factor, so that the load cell outputs a mass of the object. For example, the calibration factor may be determined by performing a measurement on a reference mass having a known mass with the load cell, or based on a known gravity “g” at the location of the load cell. The load cell may comprise an internal calibration mass for determining the calibration factor. For example, the internal calibration mass may be configured to be loaded onto, and unloaded from, a measurement area or portion of the load cell so that a measurement is performed on the internal calibration mass by the load cell. Alternatively, an external calibration mass may be used instead of an internal calibration mass. Alternatively, the load cell may output a weight of the object, without converting it to a mass. The apparatus may comprise a controller or processor that is configured to calculate a mass of the object based on the output of the load cell, for example using a calibration factor or the known gravity “g” at the location of the load cell.

The present inventors have realised that electromagnetic force compensation load cells, and indeed other types of electronic load cell, can be sensitive to ambient or local magnetic fields. In particular, an ambient or local magnetic field can affect the electromagnetic force compensation mechanism, for example such that a larger or smaller current than would otherwise be required needs to be supplied to the electromagnetic coil to prevent movement of the beam when the weight force is applied to the beam. This will lead to an error in the measurement output of the load cell, and therefore an error in the measured mass and/or change in mass of the wafer. In other words, an ambient or local magnetic field may cause an error in the measured mass and/or change in mass of the wafer.

For example, a uniform ambient or local magnetic field may lead to a uniform error in the measurement output of the load cell. Such a uniform error can typically be removed by load cell setup procedures such as a load cell calibration procedure. In contrast, a fluctuating ambient or local magnetic field may lead to fluctuations in the measurement output of the load cell (and therefore fluctuating errors in the measurement of the mass or change in mass), thereby negatively affecting the measurement repeatability and the accuracy of the measurement. In general, the presence of such ambient or local magnetic fields may reduce an overall sensitivity of the apparatus to detect small differences in mass.

Such ambient or local magnetic fields may be caused by neighbouring process or metrology equipment in a wafer fabrication environment, and/or communication devices, and/or wafer/material handling systems such as hoists, or other sources inside or outside of a mass metrology apparatus comprising the load cell, for example.

Such measurement errors may be caused by the magnetic field fluctuations directly, and/or by the local or ambient field magnetising/demagnetising a case of the load cell, depending on the magnetic remanence of the case of the load cell.

In addition to electromagnetic force compensation load cells, this issue may also be relevant for magnetostriction load cells, which are a class of load cell which work based on change in physical shape or dimensions of certain ferromagnetic materials due to an applied magnetic field (or vice versa). In addition, any load cell that uses an electromagnet or electromagnetic coil may be affected by ambient or local magnetic fields in a manner similar to that described above.

A measurement error caused by a uniform (constant) ambient or local magnetic field may be prevented or reduced by performing a calibration of the load cell to compensate for the magnetic field. Such a calibration may comprise using the load cell to measure the weight or mass of a reference mass or weight having a known mass or weight, and comparing the measured weight or mass to the known weight or mass. For example, the reference mass or weight may be an internal reference mass or weight that is internal to the load cell and that is configured to be loaded onto, and unloaded from, a measurement area or portion of the load cell so that a measurement is performed on the reference mass or weight by the load cell. Alternatively, an external reference mass or weight may be used instead of an internal reference mass or weight. Performing a single calibration in this manner can account for a uniform ambient or local magnetic field.

In an example calibration procedure, the load cell may measure a “zero” measurement value where the load cell is unloaded and then measure a reference mass or weight (internal or external) which has a known mass or weight (either “known” by the load cell (internal mass or weight) or by the user (external mass or weight)). The load cell may then compare the measured mass or weight to an expected value for the reference mass or weight and adjust an internal gain factor and a zero offset of the load cell so that the measured value aligns with the expected value. The gain factor controls the linearity of the load cell, for example to minimise errors when measuring objects across a full weighing range of the load cell, e.g. 5 g vs 120 g. This calibration procedure may therefore cancel out any systematic error due to a permanent change in the local magnetic field. The external weights are typically manufactured to meet an appropriate standard for non-magnetic calibration weights and are premeasured by the manufacturer.

Alternatively, when determining the change in mass of a wafer based on measurements performed pre-and post-processing of the wafer, the effects of a uniform ambient or local magnetic field may be cancelled out by subtracting the pre-and post-measurements, without requiring any calibration.

However, changing or transient magnetic fields may be more difficult to account for. For infrequently or slowly changing magnetic fields, it may be possible to prevent or reduce measurement errors by performing regular or periodic calibrations of the load cell. However, since each calibration takes a predetermined period of time during which the load cell cannot be used to perform a measurement on a wafer, for example 80 to 100 seconds, performing regular calibrations would reduce the throughput of the apparatus.

Furthermore, such regular or periodic calibrations would not account for changes in the magnetic field happing on a smaller timescale than the time gap between neighbouring calibrations, nor avoid errors in measurements occurring after a change in the magnetic field and before the subsequent calibration.

Furthermore, such regular or periodic calibrations may be unnecessary if the load cell is installed in an environment with a uniform magnetic field, such that time is wasted performing unnecessary calibrations and the throughput of the apparatus is reduced.

The electromagnetic force compensation mechanism of the load cell itself may be able to account for high-frequency changes in the ambient or local magnetic field occurring during a measurement.

However, lower frequency or step changes in the ambient or local magnetic field may be more problematic, particularly if they occur between regular or periodic calibrations, or on a shorter timescale than the time gap between neighbouring calibrations.

In general, changes having a duration of less than 5 seconds, or less than 2 second, or less than 1 second, may be less problematic because they may be perceived by the load cell as an instability in the load cell measurement and the load cell may wait until the measurement has stabilised before outputting a measurement. Changes having a duration in the range of 5 seconds to 60 seconds or 10 minutes may have a higher risk of affecting the mass measurement, for example. Changes having a duration of more than 1 min or more than 10 min may be cancelled out by periodic calibration of the load cell and therefore may be less problematic.

Therefore, changes in the magnetic field magnitude having a duration of 1 second to 10 minutes, for example 5 seconds to 60 seconds, may be more likely to cause errors in the measurement of the mass or change in mass.

However, changes having a duration of less than this or more than this may still cause problems, for example if the change affects a mass measurement for a wafer performed before processing of the wafer but does not affect a mass measurement for the wafer performed after processing of the wafer.

The present invention has been devised in light of the above considerations.

### SUMMARY OF THE INVENTION

At its most general, the present invention relates to providing a magnetic field sensor to monitor the magnetic field in the vicinity of the load cell. By monitoring the magnetic field, one or more different actions may be taken when a change in the magnetic field is detected.

According to a first aspect of the present invention there is provided an apparatus for measuring the mass and/or the change in mass of an object, comprising: a load cell; and a magnetic field sensor.

According to the present invention, the apparatus comprises a magnetic field sensor. Therefore, the magnetic field can be monitored and one or more different actions may be taken when a change in the magnetic field is detected.

The apparatus according to the first aspect of the present invention may have any one, or, where compatible, any combination of the following optional features.

The apparatus may be for measuring the mass and/or the change in mass of a wafer, for example a semiconductor wafer.

The apparatus may be for measuring the mass and/or the change in mass of a wafer having a predetermined diameter, for example 300 mm.

The apparatus may be configured or adapted to measure the mass and/or the change in mass of the object.

The apparatus may be a metrology apparatus, or a mass metrology apparatus, or a semiconductor wafer mass metrology apparatus, for example.

The load cell may be for measuring the weight or mass, and/or the change in weight or mass, of an object.

The load cell may be configured or adapted to measure the weight or mass, and/or the change in weight or mass, of the object

The load cell may be for weighing the object.

The load cell may be for performing a weight measurement on the object.

The load cell may be for generating measurement output indicative of the weight or mass, and/or the change in weight or mass, of the object.

The load cell may be for measuring a weight force of the object.

The load cell may comprise or be a weight force transducer.

The load cell may comprise or be a weight force sensor.

The load cell may generate measurement output based on a measurement of an amount of electromagnetic force compensation required to compensate for (or counterbalance or counteract) a weight force of an object.

The load cell may generate measurement output based on a measurement of an amount of current that needs to be supplied to an electromagnetic force compensation mechanism of the load cell to compensate for (or counterbalance or counteract) a weight force of an object.

The load cell may be configured to balance the weight force of the object with a force experienced when an electromagnetic coil of the load cell is energised in a magnetic field of the load cell. Specifically, the load cell may be configured to provide a current to the electromagnetic coil that is sufficient to cause the force experienced by the electromagnetic coil to balance the weight force of the object. The measurement output of the load cell may be generated based on the required current. The load cell may therefore comprise an electromagnetic coil arranged in a magnetic field and a controller for controlling a current supplied to the electromagnetic coil.

The load cell may comprise a permanent magnet that generates the magnetic field.

The permanent magnet may be positioned beneath or below the electromagnetic coil. Of course, the permanent magnet may be positioned differently relative to the electromagnetic coil, for example above the electromagnetic coil, and/or at the side of the electromagnetic coil, and/or inside the electromagnetic coil, and/or around the electromagnetic coil.

The electromagnetic coil and the permanent magnet may be configured to experience an attractive magnetic force between the electromagnetic coil and the permanent magnet when an appropriate current is supplied to the electromagnetic coil.

The load cell may comprise or be an electromagnetic force compensation or electromagnetic force restoration force sensor or load cell.

The load cell may comprise or be an electromagnetic force compensation or electromagnetic force restoration force sensor or load cell comprising an electromagnetic coil.

The apparatus, for example the load cell or a controller or processor of the apparatus, may be configured to calculate or determine the mass and/or change in mass of the object based on at least a measurement performed on the object by the load cell.

The load cell, or the apparatus, may comprise a controller or processor that is configured to multiply a measurement result of the load cell (for example a measurement of a weight force of the object by the load cell) by a predetermined calibration factor, to determine a mass and/or a change in mass of the object. For example, the calibration factor may be determined by performing a measurement on a reference mass having a known mass with the load cell, or based on a known gravity “g” at the location of the load cell. Specifically, the load cell may measure a weight force or a change in weight force of the object, and the weight force or change in weight force may then be converted into a mass or change in mass of the object. The load cell may comprise an internal calibration mass for determining the calibration factor. Alternatively, an external calibration mass may be used instead. Alternatively, the load cell may output a weight of the object, without converting it to a mass. The apparatus may comprise a controller or processor that is configured to calculate a mass of the object based on the output of the load cell, for example using a calibration factor or the known gravity “g” at the location of the load cell.

The load cell may comprise an internal calibration mechanism that is configured to calibrate the load cell so that the load cell outputs a mass and/or a change in mass of the object based on a measurement of the weight force of the object.

The calibration procedure may comprise determining a gain and/or an offset for the load cell, based on a measurement performed on an internal or external reference mass or weight having a known or predetermined mass or weight.

In one example, the reference mass or weight may be a reference wafer having a known mass or weight. The calibration procedure may comprise determining and/or correcting a drift of the measurement output of the load cell over time. For example, the calibration procedure may comprise measuring a reference wafer and comparing the measurement result with the known weight or mass of the reference wafer. The resulting difference or offset can then be added to the measurement output or results for other wafers measured by the load cell.

A calibration procedure may be performed periodically, for example every 5 to 15 minutes, or every 8 to 10 minutes.

The apparatus and/or the load cell may comprise a support for supporting the object during a measurement performed by the load cell.

The support may be configured or adapted to support the object during the measurement.

The support may be or comprise a pan. The term support may therefore be replaced with the term pan throughout, unless incompatible. The pan may be a weighing pan or a balance pan.

The support may be a weighing support.

The support may comprise a support part for supporting the object and a mounting part for mounting the support on the load cell. For example, the mounting part may comprise a shaft such as a longitudinal shaft. These parts may be integral, or connected, for example.

The support may comprise a pan part and a shaft connected to the pan part. The shaft may be a longitudinal shaft.

The support may be mounted on the load cell, or coupled to the load cell, or connected to the load cell.

Supporting an object may mean supporting the weight of the object.

Supporting an object may mean holding or carrying the object.

The magnetic field sensor is typically arranged in the vicinity of the load cell so as to measure a magnetic field in the vicinity of the load cell.

The magnetic field sensor may be integral to the load cell, or part of the load cell, or internal to the load cell. Alternatively the magnetic field sensor may be outside of the load cell or separate to the load cell or spaced apart from the load cell.

The magnetic field sensor may be configured to measure an ambient or local magnetic field for the apparatus or load cell, or an ambient or local magnetic field in the apparatus.

For example, the magnetic field sensor may be positioned less than 100 cm, or less than 50 cm, or less than 20 cm, or less than 10 cm from the load cell.

The magnetic field sensor may be positioned less than 100 cm, or less than 50 cm, or less than 20 cm, or less than 10 cm from an electromagnetic coil of the load cell.

A centre of a sensing element of the magnetic field sensor, for example a centre of an electromagnetic coil of the magnetic field sensor, may be positioned less than 100 cm, or less than 50 cm, or less than 20 cm, or less than 10 cm from a centre of an electromagnetic coil of the load cell.

The magnetic field sensor may be positioned greater than a predetermined distance from the load cell, for example greater than a predetermined distance from an electromagnetic coil of the load cell. For example, the magnetic field sensor may be positioned more than 1 cm, or more than 2 cm, or more than 3 cm from the load cell.

More specifically, a centre of a sensing element of the magnetic field sensor, for example a centre of an electromagnetic coil of the magnetic field sensor, may be positioned greater than the predetermined distance (for example 1 cm, or 2 cm, or 3 cm) from the load cell, for example greater than the predetermined distance from a centre of an electromagnetic coil of the load cell.

As mentioned above, in some embodiments the magnetic field sensor may be internal to the load cell. For example, the load cell may comprise the magnetic field sensor and the magnetic field sensor may be positioned inside the load cell close to the electromagnetic coil of the load cell.

The magnetic field sensor may be or comprise a magnetometer.

The magnetometer may be a Hall effect magnetometer, or a rotating coil magnetometer, or a fluxgate magnetometer, or a magnetoresistive magnetometer, for example.

The magnetometer may be a vector magnetometer, which provides both direction and magnitude of the magnetic field.

The magnetometer may be configured to measure magnetic fields in the range of 1 μG to 1 G (Gauss) for example, or 100 μG to 1 G, for example.

The magnetic field sensor may be configured or arranged to measure an ambient or local magnetic field near to, or in the vicinity of, or local to, or ambient to, or proximal to, or around, or adjacent to, or internal to, or inside, the load cell.

The magnetic field sensor may be configured or arranged to measure an ambient or local magnetic field of, or in, or around, the apparatus.

The apparatus may comprise a single magnetometer, or a plurality of magnetometers.

The magnetometer may be configured to measure a magnitude of the magnetic field.

The magnetometer may be configured to measure a magnitude and a direction of the magnetic field. The magnetometer may therefore measure a vector value of the magnetic field.

The magnetometer may be configured to measure a magnitude of the magnetic field in each of three perpendicular axes, for example the x, y and z axes.

The apparatus may be configured to periodically or continuously monitor an output of the magnetic field sensor.

For example, the apparatus may comprise a controller or processor that is configured to periodically or continuously monitor an output of the magnetic field sensor.

The apparatus may be configured to identify or detect or sense an event based on an output of the magnetic field sensor.

For example, the apparatus may comprise a controller or processor that is configured to identify or detect an event based on an output of the magnetic field sensor.

The event may be a change in the output of the magnetic field sensor, or a change in the magnetic field measured by the magnetic field sensor.

The event may be a change in the output of the magnetic field sensor, or a change in the magnetic field measured by the magnetic field sensor, that is greater than or equal to a predetermined value. For example, the predetermined value may be 5 mG, or 3 mG, or 1 mG.

The predetermined value may be predetermined based on a sensitivity or precision of the load cell or apparatus. For example, a load cell or apparatus with a precision of <60 μg may accommodate changes in the magnetic field of up to 5 mG without significant errors in the measurement output, whereas a load cell or apparatus with a precision of <30 μg may only be able to accommodate changes in the magnetic field of up to 1 to 3 μg, and a load cell or apparatus with a precision of <10 μg may only be able to accommodate changes in the magnetic field of up to 1 μg.

The change in the output of the magnetic field sensor or the change in the magnetic field measured by the magnetic field sensor may be measured or calculated relative to a predetermined value, for example an output of the magnetic field sensor or a magnetic field measured by the magnetic field sensor at a predetermined time, such as the last time that the load cell was calibrated.

More generally, the apparatus may be configured to determine when a change in an output of the magnetic field sensor or a change in the magnetic field measured by the magnetic field sensor is greater than or equal to a predetermined value.

The apparatus may be configured to perform an action or control an operation of the apparatus based on an output of the magnetic field sensor.

For example, the apparatus may comprise a controller or processor that is configured to perform an action or control an operation of the apparatus based on an output of the magnetic field sensor.

Various different actions or operations are possible with the present invention.

For example, the apparatus (for example a controller or processor of the apparatus) may be configured to trigger or perform or schedule a calibration of the load cell based on an output of the magnetic field sensor.

For example, the apparatus may be configured to trigger or perform or schedule the calibration of the load cell when the apparatus determines that a change in an output of the magnetic field sensor or a change in a magnetic field measured by the magnetic field sensor is greater than or equal to a predetermined value. The calibration may be configured to correct the output of the load cell for the effects of the magnetic field or the change in the magnetic field.

The calibration may comprise determining a gain and/or an offset for applying to, or correcting, a measurement output of the load cell or apparatus.

In addition, or alternatively, the apparatus (for example a controller or processor of the apparatus) may be configured to provide information to a user based on the output of the magnetic field sensor, and/or based on the identification or detection of the event. For example, the apparatus may be configured to inform the user that there has been a change in an ambient or local magnetic field, for example if the change in the magnetic field is greater than a predetermined amount, which may be determined relative to the magnetic field when the load cell was previously calibrated.

This information may be provided to the user visually, for example via a display or a visual indicator, or audibly, via an audible indicator. The apparatus may be configured to inform or alert the user of the need to perform a calibration of the load cell or to take other action. The user may then be able to take appropriate action, for example manually initiating a calibration of the load cell, based on the information or alert.

Alternatively, or in addition, the apparatus may be configured to stop or temporarily pause performing measurements when the apparatus determines that a change in an output of the magnetic field sensor or a change in a magnetic field measured by the magnetic field sensor is greater than or equal to a predetermined value. The predetermined value may correspond to a relatively large or high change in the magnetic field, for example a change of more than 300 mG, or more than 500 mG.

Alternatively, or in addition, the apparatus (for example a controller or processor of the apparatus) may be configured to determine an error in a measurement performed by the load cell based on a measurement output of the magnetic field sensor.

The apparatus may further be configured to correct the measurement performed by the load cell based on the determined error, for example by adding or subtracting the determined error from the measurement.

The apparatus may be configured to determine the error in the measurement performed by the load cell based on the measurement output of the magnetic field sensor using a predetermined relationship, equation or table. The predetermined relationship, equation or table may be specifically determined for that load cell and/or may be determined in advance.

The predetermined relationship, equation or table may relate or correspond different magnetic fields or changes of magnetic fields to different errors in the measurement performed by the load cell or different errors in the measurement output or measurement result.

The predetermined relationship, equation or table may be predetermined in advance by measuring the error in the measurement performed by the load cell that is caused by different ambient or local magnetic fields, for example by measuring the error in the measured mass or change in mass that is caused by different ambient or local magnetic fields. In particular, this may involve performing different measurements of the weight or mass of a reference mass or weight using the load cell for different ambient or local magnetic fields.

The magnetic field sensor may be configured to measure a magnetic field in each of three perpendicular axes, and the apparatus may be configured to determine the error in the measurement performed by the load cell based on the measured magnetic field in each of the three perpendicular axes.

The three components of the magnetic field may be measured independently or separately, or as a single vector quantity. It may be preferable to measure the three components independently or separately rather than as a single vector quantity because the load cell may have different sensitivities to magnetic fields in different directions.

The three components may be measured by a single magnetic field sensor that is configured to independently or separately measure the three directional components of the magnetic field, or by three sensors that are differently oriented to independently or separately measure the three directional components of the magnetic field. For example, there may be three sensors each of which is configured to measure the magnetic field strength or magnitude along only a respective single predetermined direction.

As mentioned above, the sensitivity of the load cell to an ambient or local magnetic field may be different for different directions of the ambient or local magnetic field. This may be due to the design of the internal mechanism, for example.

For example, an internal electromagnet coil and permanent magnet in the load cell may generate magnetic fields that are non-uniform and therefore their relative arrangement in the load cell may affect the net magnetic field. The arrangement of these components may therefore be more/less sensitive to magnetic field changes in the x, y, or z axes. In addition the load cell mechanism may be designed to move freely in one axis (e.g. z) and may be restricted in other axes (e.g. x, or y). Therefore, changes to the magnetic field in an orthogonal direction may have little or no effect on the forces experienced by the load cell mechanism. However, some alternative load cells may be equally affected by magnetic fields in different directions.

The apparatus may be configured to determine the error in the measurement performed by the load cell based on the measured magnetic field in each of the three perpendicular axes using a respective predetermined relationship, equation or table for each of the three perpendicular axes.

Alternatively, the apparatus may be configured to determine the error in the measurement performed by the load cell (for example weight or mass) based on a vector quantity of the measured magnetic field.

The apparatus may be configured to correct the measurement performed by the load cell based on the determined error in the measurement. For example, the apparatus (for example a controller or processor of the apparatus) may be configured to add or subtract the determined error from the measurement performed by the load cell.

The measurement performed by the load cell may comprise measurement of a weight or mass of an object loaded onto the load cell. A measurement output of the load cell may be, or indicate, or correspond to, a weight or mass of the object loaded on the load cell.

The load cell may be an electromagnetic force compensation load cell.

The load cell may comprise an electromagnetic force compensation mechanism.

The apparatus may be configured to calculate the mass and/or the change in mass of an object loaded onto the load cell based at least on a measurement performed by the load cell.

The apparatus may further comprise a controller or processor that is configured to calculate the mass and/or the change in mass of the object based at least on a measurement performed by the load cell, and/or an output of the load cell.

The controller or processor may be integral to the load cell, or part of the load cell, or external to the load cell.

The apparatus may further comprise one or more sensors configured to sense one or more atmospheric conditions. For example, the one or more sensors may be arranged to sense one or more atmospheric conditions inside the measurement chamber.

For example, the one or more sensors may be configured to sense one or more of a pressure or temperature or humidity of the air surrounding the load cell and/or the air in the measurement chamber.

The apparatus may further comprise a controller or processor that is configured to calculate the mass and/or the change in mass of the object based at least on a measurement performed by the load cell, or an output of the load cell, and an output of the one or more sensors.

For example, the controller or processor may be configured to calculate a buoyancy force acting on the object based on the output of the one or more sensors and to correct a weight or mass measurement for the object based on the calculated buoyance force.

The controller may be configured to correct the measurement of the mass and/or the change in mass for the effects of buoyancy acting on the object based on the output of the one or more sensors.

The apparatus may comprise a measurement chamber in which the load cell is housed, wherein the magnetic field sensor is located inside the measurement chamber.

The measurement chamber may provide a controlled environment around the load cell, for example to minimise measurement errors caused by air currents.

The measurement chamber may comprise, or be made of or substantially made of, aluminium, for example, which has a low magnetic permeability and therefore does not provide significant magnetic shielding of the load cell.

The load cell may comprise a housing, wherein the magnetic field sensor is located outside the housing.

The housing may be made of aluminium, for example.

The apparatus may comprise a magnetic shield that is configured to at least partially magnetically shield at least part of the load cell.

The magnetic shield may be in the form of a housing or case or shell that substantially surrounds the load cell.

The magnetic shield may comprise a material having a high magnetic permeability, such as Mu metal.

The magnetic field sensor may be inside of the magnetic shield (on the same side of the magnetic shield as the load cell).

The apparatus may comprise one or more magnetic field generators, wherein the apparatus is configured to control the one or more magnetic field generators based on an output of the magnetic field sensor.

For example, the apparatus (such as a controller or processor of the apparatus), may control a power or current supplied to the one or more magnetic field generators to control a magnitude and/or a direction of a magnetic field generated by the one or more magnetic field generators.

The one or more magnetic field generators may comprise an electromagnetic coil.

In one example the magnetic field generator may comprise a magnetic field sensor, Helmholtz coils and current generators. The coils may be oriented so their axes are aligned in the x, y and z directions. The sensor may measure the field and the currents in the coils may be adjusted to bring the net field to zero or a predetermined value or transient fluctuations are eliminated/reduced.

The apparatus may be configured to control the one or more magnetic field generators to reduce a magnitude of an output of the magnetic field sensor. In other words, the one or more magnetic field generators may be configured to reduce a magnitude of an ambient or local magnetic field that is detected by the magnetometer.

The apparatus may be configured to control the one or more magnetic field generators to generate a magnetic field that is opposite to, or that opposes, or that counteracts, or that cancels, an ambient or local magnetic field detected by the magnetometer.

The apparatus may be for measuring the mass and/or the change in mass of a semiconductor wafer.

The apparatus may comprise a plurality of magnetic field sensors, each of which is configured to measure a magnetic field strength or magnitude in a respective predetermined direction. For example, the apparatus may comprise three magnetic field sensors, each of which is arranged to measure the magnetic field strength in a respective one of mutually perpendicular x, y and z directions. Alternatively, there may be a single magnetic sensor configured to measure the magnetic field strength in each of these three directions.

The apparatus may comprise a plurality of magnetic field sensors, and the apparatus may be configured to calculate a magnetic field at a position between at least two of the plurality of magnetic field sensors based on outputs of the at least two magnetic field sensors.

For example, the at least two magnetic field sensors may be located on opposite sides of the load cell, and the apparatus may be configured to calculate or estimate the magnetic field at a position in the load cell between the two magnetic field sensors based on the measurement outputs of the two load cells and information about the positions of the two magnetic field sensors relative to the position in the load cell.

For example, the position in the load cell may be a position of an electromagnetic coil in the load cell, for example the position of a centre of the electromagnetic coil.

According to a second aspect of the present invention there is provided a method performed by the apparatus according to any one of the preceding claims, the method comprising: measuring a magnetic field with the magnetic field sensor; and performing an action or controlling an operation of the apparatus based on the measurement of the magnetic field.

The method according to the second aspect of the present invention may have any of the features of the apparatus according to the first aspect of the present invention discussed above or below.

The method may be a mass metrology method, or a wafer mass metrology method.

According to a third aspect of the present invention there is provided a method comprising: loading an object on a load cell; exposing the load cell to a first magnetic field; performing a first measurement on the object with the load cell while the load cell is exposed to the first magnetic field; exposing the load cell to a second magnetic field different to the first magnetic field; and performing a second measurement on the object with the load cell while the load cell is exposed to the second magnetic field.

The magnetic field may be generated using an electromagnetic coil positioned adjacent to, or around, the load cell, for example.

The method may comprise determining a sensitivity of the load cell to a magnetic field based on at least the first measurement and the second measurement.

The sensitivity of the load cell may be expressed as a ratio of the error in a measurement output of the load cell to a change in the ambient or local magnetic field relative to a predetermined value when the measurement was performed, for example with the units of μg/mG. The predetermined value may be a measurement output of the magnetic field sensor at the time that the load cell was last calibrated.

The method may comprise determining a relationship, equation or table that relates the magnetic field to an error in a measurement performed by the load cell when the load cell is exposed to that magnetic field based on at least the first measurement and the second measurement.

The method comprises: sequentially exposing the load cell to three or more different magnetic fields; and performing a measurement of the object while the load cell is exposed to each of the three or more different magnetic fields.

Different magnetic fields in different directions may be applied to the load cell, to determine if the sensitivity of the load cell differs depending on the direction of the magnetic field, and to fully characterise the sensitivity of the load cell.

The invention includes the combination of the aspects and preferred features described except where such a combination is clearly impermissible or expressly avoided.

### SUMMARY OF THE FIGURES

Embodiments and experiments illustrating the principles of the invention will now be discussed with reference to the accompanying figures in which:

FIG. 1 is a schematic illustration of part of a load cell that can used in an embodiment of the present invention.

FIG. 2 is a schematic illustration of a load cell that can be used in an embodiment of the present invention.

FIG. 3 is a schematic illustration of an apparatus according to an embodiment of the present invention.

FIG. 4 is a schematic illustration of an apparatus according to an embodiment of the present invention.

FIG. 5 is a schematic illustration of an apparatus according to an embodiment of the present invention.

FIG. 6 shows experimental results obtained using the apparatus illustrated in FIG. 5.

FIG. 7 shows experimental results obtained using the apparatus illustrated in FIG. 5.

FIG. 8 shows experimental results obtained using the apparatus illustrated in FIG. 5.

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

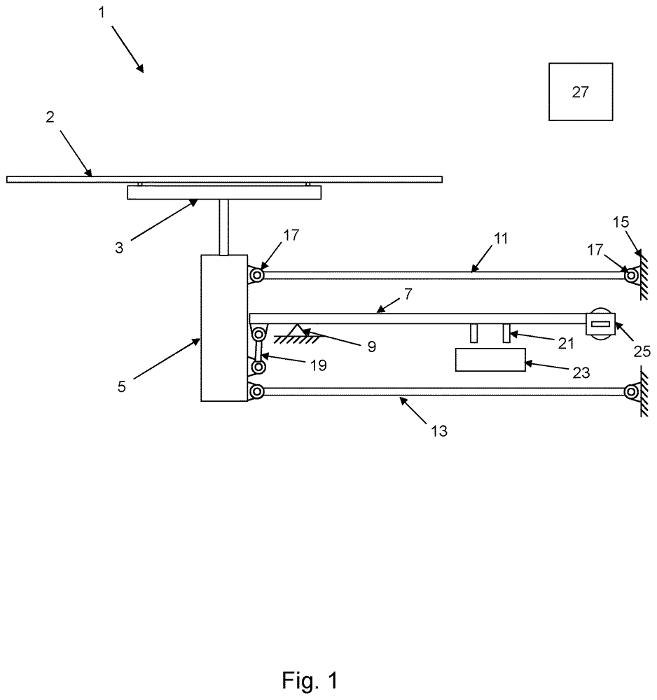

FIG. 1 is a schematic illustration of part of a load cell that can be used in an embodiment of the present invention. Of course, the part of the load cell illustrated in FIG. 1 is merely an example and other types or configurations of load cells may alternatively be used in embodiments of the present invention.

The load cell 1 is an electromagnetic force compensation load cell, or electromagnetic force restoration load cell.

FIG. 1 illustrates the load cell 1 with a case or housing of the load cell 1 removed. FIG. 1 therefore schematically illustrates an internal mechanism of the load cell 1.

As shown in FIG. 1, the load cell 1 comprises a pan 3 that is mounted on a shaft 5. The pan 3 is for supporting a wafer 2 while the weight or mass of the wafer 2 is measured using the load cell 1. The pan 3 may be substantially circular in shape when viewed from above, for example. As shown in FIG. 1, the pan 3 has a plurality of pins (or other protrusions such as bumps or balls) that extend from the upper surface of the pan 3 so as to contact a lower surface of the wafer 2 and support the wafer 2 spaced apart from the upper surface of the pan 3. For example, there may be three such pins.

The shaft 5 is connected to a beam 7 (or balance lever) on a first side of a pivot 9 around which the beam 7 can pivot. The connection is such that vertical movement of the shaft 5 acts to cause pivoting of the beam 7 around the pivot 9.

The load cell 1 further comprises an upper linkage 11 and a lower linkage 13. The upper linkage 11 and lower linkage 13 are each rotatably connected at a respective first end to the shaft 5 and at a respective second end to a fixed surface 15 by rotatable connections 17. The upper linkage 11 is connected to an upper portion of the shaft 5 and is located above the beam 7. The lower linkage 13 is connected to a lower portion of the shaft 5 and is located below the beam 7. The upper linkage 11 and lower linkage 13 may be rods or beams, for example. The upper linkage 11 and lower linkage 13 define or constrain possible motion of the shaft 5.

The shaft 5 is connected to the beam 7 via a third linkage 19 that is rotatably connected at its first end to the shaft 5 and that is rotatably connected at its second end to the beam 7. Of course, other connections between the shaft 5 and beam 7 are possible.

When an object is loaded onto the pan 3, the weight force of the object acts on the pan 3 and the shaft 5 to move the pan 3 and the shaft 5 downwards. The connection between the shaft 5 and the beam 7 means that when an object is loaded on the pan 3, a downwards force is applied to the beam 7 on the first side of the pivot 9. This downwards force acts to rotate the beam 7 in an anti-clockwise (counter-clockwise) direction around the pivot 9 when the shaft 5 moves downwards.

The load cell 1 further comprises an electromagnetic force compensation mechanism for generating a force on the beam 7 on the second side of the pivot 9, so as to balance out the force on the beam on the first side of the pivot 9 due to the weight of the object loaded on the pan 3.

Specifically, the electromagnetic force compensation mechanism comprises an electromagnetic coil 21 that is positioned on the beam 7 (or attached to the beam 7) on the second side of the pivot 9. Furthermore, the electromagnetic force compensation mechanism further comprises a magnet 23 that is positioned close to the electromagnetic coil 21, for example beneath the electromagnetic coil 21. The magnet 23 may be a permanent magnet or an electromagnet. Typically, it is a permanent magnet.

Rotation of the beam 7 in the anti-clockwise direction as described above would cause the electromagnetic coil 21 to move upwards, away from the magnet 23.

When an electrical current is applied to the electromagnetic coil 21, the electromagnetic coil 21 produces a magnetic field. The interaction between the magnetic field produced by the electromagnetic coil 21 and the magnetic field produced by the magnet 23 causes the electromagnetic coil 21 to experience a force, the magnitude and direction of which is determined by the magnitude and direction of the current applied to the electromagnetic coil 21.

By applying a current with a suitable magnitude and direction to the electromagnetic coil 21, the electromagnetic coil 21 can be made to experience a downwards force towards the magnet 23 that causes a moment of force on the beam 7 that is equal and opposite to the moment of force on the beam 7 due to the weight of the object loaded on the pan 3.

In particular, a suitable current applied to the electromagnetic coil 21 can cause an attractive magnetic force between the electromagnetic coil 21 and the magnet 23, which acts in a downwards direction on the electromagnetic coil 21, since the magnet 23 is positioned beneath the electromagnetic coil 21, for example directly below the electromagnetic coil 21.

The electromagnetic coil 21 therefore experiences an attractive force with the magnet 23, which acts on the electromagnetic coil 21 in a downwards direction towards the magnet 23, when a suitable current is supplied to the electromagnetic coil 21.

The downwards force on the electromagnetic coil 21, and therefore the moment of force caused by the downwards force, depends on the magnitude of the current applied to the electromagnetic coil 21. Therefore, the moment of force caused by the weight of the object on the pan 3 can be determined by measuring the magnitude of the current that needs to be supplied to the electromagnetic coil 21 in order to keep the electromagnetic coil 21 in the same position when the object is placed on the pan 3. The current that needs to be supplied to the electromagnetic coil 21 in order to keep the electromagnetic coil 21 in the same position when the object is placed on the pan 3 is therefore directly related to the weight of the object, and can be used to calculate the weight and/or mass of the object.

The load cell 1 further comprises a position sensor 25 for detecting a position of part of the beam 7, for example the position of an end of the beam 7. Specifically, the position sensor 25 is for detecting when the part of the beam 7 is in a predetermined position. The part of the beam 7 may be in the predetermined position when the beam 7 is horizontal, which may be a default or rest orientation of the beam 7 when no object is loaded on the pan 3. Therefore, the part of the beam 7 being in the predetermined position may indicate that the beam 7 is in the default or rest orientation of the beam 7.

The position sensor may be an optical sensor that comprises a light source and a light sensor, wherein a light path between the light source and the light sensor is blocked when the part of the beam 7 is not in the predetermined position. For example, the part of the beam 7 may comprise an opening or aperture through which the light can pass and that is aligned with the light source and the light sensor when the part of the beam 7 is in the predetermined position.

The load cell 1 further comprises a controller or processor 27 that is configured to control a current supplied to the electromagnetic coil 21 based on an output of the position sensor 25. Specifically, the controller or processor 27 controls a magnitude of the current supplied to the electromagnetic coil 21 such that the position sensor 25 detects that the part of the beam 7 is in the predetermined position when the object is loaded on the pan 3. This corresponds to the force on the electromagnetic coil 21 balancing out the force on the beam 7 on the first side of the pivot 9 due to the weight of the object loaded on the pan 3. The controller 27 may comprise a processor or microprocessor, for example.

In other words, the controller 27 is configured to control the supply of current to the electromagnetic coil 21 and to determine the current that needs to be supplied to the electromagnetic coil 21 to keep the electromagnetic coil 21 and therefore the pan 3 in the same positions when the object is loaded on to the pan 3.

The load cell 1 (for example the controller 27) may determine and output the weight of an object loaded on the load cell 1, based on the current that needs to be supplied to the electromagnetic coil 21 to maintain the electromagnetic coil 21 and therefore the pan 3 in position when the object is loaded on the pan 3. Alternatively, the load cell 1 may determine and output the mass of an object loaded on the load cell 1, for example using a calibration factor that is determined by performing a measurement on a reference mass or weight having a known mass or weight with the load cell 1, or based on a known gravity “g” at the location of the load cell 1. For example, the calculated weight of the object may be multiplied by the calibration factor to covert the weight into a mass. The load cell 1 may comprise an internal calibration mass for determining the calibration factor, which can be loaded onto the pan 3 or shaft 5 and unloaded from the pan 3 or shaft 5. Alternatively, an external calibration mass may be used instead of an internal calibration mass. The calibration mass could be a steel weight for example, or a reference wafer (a wafer having a known mass). As is well known, the weight and mass of the object are related together by the well-known equation W=mg, where W is the weight, m is the mass and g the gravity at the location. The apparatus may comprise a controller or processor that is configured to calculate a mass of the object based on the output of the load cell, for example using a calibration factor or the known gravity “g” at the location of the load cell.

Calibration of the load cell 1 may comprise determining both an offset and a gain for the load cell necessary to convert the output of the load cell into a mass.

Of course, the load cell 1 described above and illustrated in FIG. 1 is only an example of a suitable load cell, and other types or configurations of load cell can be used in the present invention.

In particular, other types of electromagnetic force compensation load cells are known, for example where both the weight force of the object and the electromagnetic force act on a beam on the same side of the pivot in opposite directions.

In addition, or alternatively, various changes can be made to the load cell 1 illustrated in FIG. 1. For example, the position sensor may be arranged to detect a position of the pan 3, shaft 5 or electromagnet 21 instead of part of the beam 7, or another component connected directly or indirectly to any of these components.

Furthermore, a configuration and/or position of the electromagnetic coil 21 and magnet 23 may be different to those illustrated in FIG. 1.

Furthermore, the connection between the shaft 5 and the beam 7 may be different to that illustrated in FIG. 1.

Furthermore, the upper and lower linkages 11 and 13 may be omitted in some embodiments.

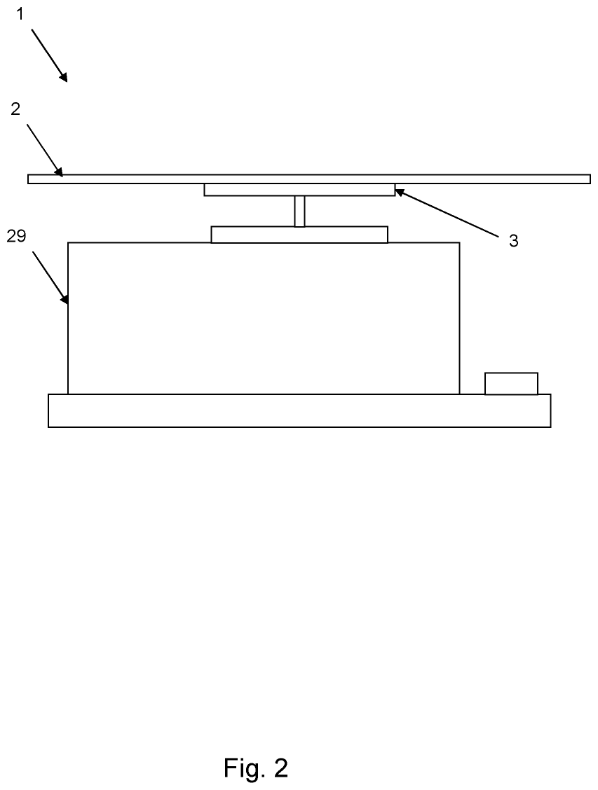

FIG. 2 shows the load cell 1 including a case or housing 29 of the load cell, which houses the internal mechanism of the load cell 1 illustrated in FIG. 1.

The case or housing 29 is made of a material with a relatively low magnetic permeability, and therefore provides no or minimal magnetic shielding of the load cell 1. For example, the case or housing 29 may comprise aluminium.

As mentioned above, the present inventors have realised that electromagnetic force compensation load cells such as the load cell 1 illustrated in FIG. 1, and indeed other types of electronic load cell, can be sensitive to ambient or local magnetic fields. In particular, an ambient or local magnetic field can impact the electromagnetic force compensation mechanism, for example such that a larger or smaller current than would otherwise be required needs to be supplied to the electromagnetic coil to prevent movement of the beam. This will lead to an error in the measurement output of the load cell, and therefore an error in the measured mass or change in mass of the wafer.

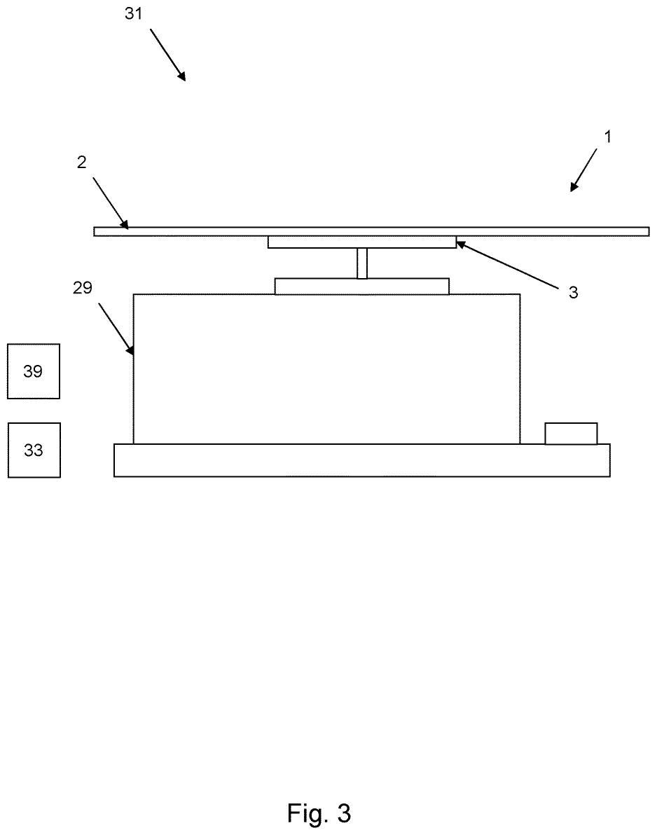

FIG. 3 shows an apparatus 31 according to an embodiment of the present invention. The apparatus 31 includes the load cell 1 illustrated in FIG. 2. In addition, the apparatus 31 further comprises a magnetometer 33 that is arranged to measure the magnetic field in the vicinity of the load cell 1.

In particular, the magnetometer 33 is positioned in the vicinity of the load cell 1, for example external to the case or housing 29 of the load cell 1 but within a predetermined distance of the load cell 1.

Of course, in another embodiment, the magnetometer 33 may be located inside the case or housing 29 of the load cell 1 and/or may be part of the load cell 1.

The magnetometer 33 may be positioned within (less than) a first predetermined distance of the electromagnetic coil 21 of the load cell 1. For example, the magnetometer 33 may be positioned less than 1 m from the electromagnetic coil 21 of the load cell 1, or less than 50 cm, or less than 20 cm, or less than 10 cm, or less than 5 cm.

More specifically, a centre of a sensing element of the magnetometer 33, for example a centre of an electromagnetic coil of the magnetometer, may be positioned less than the first predetermined distance from a centre of the electromagnetic coil 21 of the load cell 1.

The magnetometer 33 may be positioned greater than a second predetermined distance from the electromagnetic coil 21 of the load cell.

More specifically, a centre of a sensing element of the magnetometer 33, for example a centre of an electromagnetic coil of the magnetometer 33, may be positioned greater than the second predetermined distance from a centre of the electromagnetic coil 21 of the load cell 1.

The second predetermined distance may be 1 cm, or 2 cm, or 3 cm, for example.

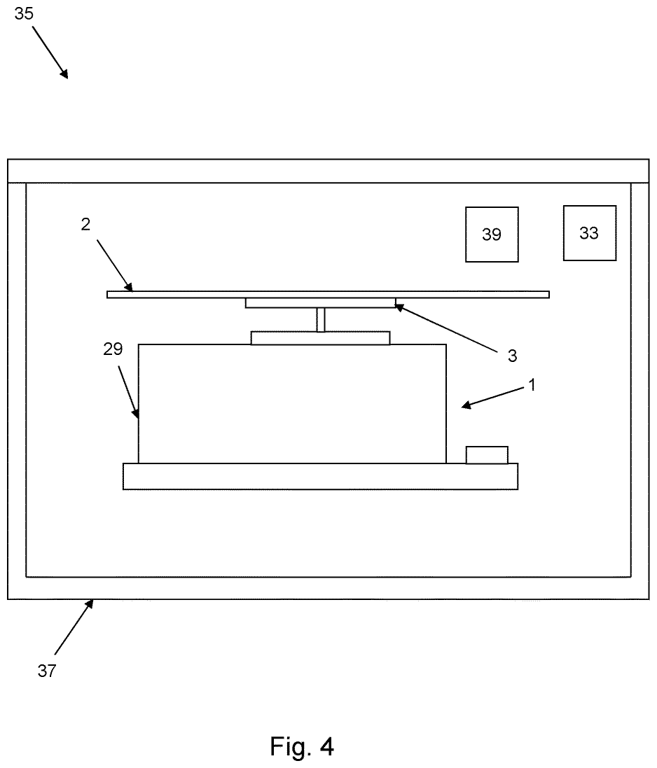

FIG. 4 shows an apparatus 35 according to a further embodiment of the present invention. The apparatus 35 differs from the apparatus 31 illustrated in FIG. 3 in that it further comprises a measurement chamber 37 in which the load cell 1 and magnetometer 33 are located. The apparatus may otherwise have any of the features of the apparatus 31 described above. The magnetometer 33 is therefore arranged to measure a magnetic field in the vicinity of the load cell 1 inside the measurement chamber 37.

The measurement chamber 37 is made of aluminium, which provides no or minimal magnetic shielding. The measurement chamber 37 provides a controlled atmosphere around the load cell 1, to reduce errors in the measurement of the mass and/or the change in mass that may otherwise be caused by convection currents and changes in temperature, pressure and humidity, for example.

The measurement chamber 37 may comprise a removable or openable lid, for inserting a wafer into the measurement chamber.

Alternatively, the measurement chamber 37 may instead comprise an opening or slot through which the wafer can be inserted to introduce the wafer into the measurement chamber 37. There may be a movable shutter or seal for selectively closing the opening or slot.

The magnetometer 33 in any of the embodiments may be configured to measure a magnitude of the magnetic field.

The magnetometer 33 may be configured to measure a magnitude and a direction of the magnetic field.

The magnetometer 33 may be configured to output a single value for the magnitude and/or direction of the magnetic field.

The magnetometer 33 may be configured to measure the magnitude of the magnetic field in each of three perpendicular axes x, y and z. The magnetometer may therefore separately measure the magnetic field component Bx in the x direction, the magnetic field component By in the perpendicular y direction, and the magnetic field component Bz in the perpendicular z direction.

It is preferable that the magnetometer 33 measures the magnitude of the magnetic field in each of the three perpendicular axes (for example separately or independently), because the sensitivity of the load cell 1 to the ambient or local magnetic field may be different for different orientations or directions of the magnetic field in some embodiments. This may be measured as three values, or as a single vector value, for example.

The apparatuses 31 and 35 further comprise a controller or processor 39 that is configured to receive an output of the magnetometer 33. The controller or processor 39 may also be configured to receive an output of the load cell 1.

The controller or processor 39 may be configured to monitor the output of the magnetometer 33, for example periodically or continuously.

The controller or processor 39 may be configured to perform an operation, or take an action, based on the output of the magnetometer 33. Various different actions or operations are possible, and the present invention is not limited to taking a specific action or performing a specific operation.

In one embodiment, the controller or processor 39 may be configured to identify or detect an event based on the output of the magnetometer 33. For example, the event may be a change in the measurement output of the magnetometer 33, or a change in the measurement output of the magnetometer 33 that is greater than or equal to a predetermined threshold value. The change may be calculated or determined relative to a predetermined value, for example a measurement output of the magnetometer when the load cell 1 was last calibrated. The event may therefore be or relate to a change in the ambient or local magnetic field, for example that is greater than a predetermined threshold value, for example relative to the ambient or local magnetic field when the load cell was last calibrated.

In one embodiment, the controller or processor 39 may be configured to control the apparatus or load cell 1 to perform a calibration of the load cell 1 based on the output of the magnetometer 33, and/or based on the identification or detection of the event.

For example, the controller or processor 39 may be configured to trigger a calibration of the load cell based on the output of the magnetometer 33, and/or based on the identification or detection of the event. For example, the controller or processor 39 may be configured to calculate a change in the magnetic field measured by the magnetometer 33 and to trigger a calibration of the load cell if the change in the magnetic field is greater than a predetermined amount, for example 5 mG. The change may be relative to the magnetic field when the load cell was most recently or previously calibrated.

Calibrating the load cell 1 may comprise loading a reference mass or weight having a known mass or weight onto the load cell 1, performing a measurement on the reference mass or weight, and comparing the measured mass or weight with the known mass or weight. The reference mass or weight may be an internal reference mass or weight, i.e. inside the case or housing 29 of the load cell, or an external reference mass or weight, i.e. outside the case or housing 29 of the load cell. The external reference mass or weight may be a reference semiconductor wafer for example. The controller or processor 39 may be configured to calculate a calibration factor based on the calibration, and to correct subsequent measurement values based on the calibration factor, for example by multiplying subsequent measurement values by the calibration factor. The controller or processor 39 may be configured to determine an offset based on the calibration and/or a gain based on the calibration.

In an example calibration procedure, the load cell 1 may measure a “zero” where the load cell 1 is unloaded and then measure a reference weight (internal or external) which has a known weight (either “known” by the load cell 1 (internal weight) or by the user (external weight)). The load cell 1 may then compare the measured weight to an expected value for the reference weight and adjust an internal gain factor and a zero offset of the load cell 1 so that the measured value aligns with the expected value. The gain factor controls the linearity of the load cell 1, for example to minimise errors when measuring objects across a full weighing range of the load cell, e.g. 5 g vs 120 g. This calibration procedure may therefore cancel out any systematic error due to a permanent change in the local magnetic field. The external weights are typically manufactured to meet an appropriate standard for non-magnetic calibration weights and are premeasured by the manufacturer.

In this manner, a calibration of the load cell 1 may only be performed when it is determined that a calibration is required due to a change in the ambient or local magnetic field. The throughput of the apparatus may therefore be increased relative to an alternative arrangement in which a calibration is regularly or periodically performed regardless of any changes to the ambient or local magnetic field.

Alternatively, or in addition, the controller or processor 39 may be configured to provide information to a user based on the output of the magnetometer 33, and/or based on the identification or detection of the event. For example, the controller or processor 39 may be configured to inform the user that there has been a change in the ambient or local magnetic field, for example if the change in the magnetic field is greater than a predetermined amount, which may be determined relative to the magnetic field when the load cell was previously calibrated. This information may be provided to the user visually, for example via a display or a visual indicator, or audibly, via an audible indicator. The controller or processor 39 may be configured to inform or alert the user of the need to perform a calibration of the load cell or to take other action. The user may then be able to take appropriate action, for example manually initiating a calibration of the load cell, based on the information or alert.

In an alternative embodiment, the controller or processor 39 may be configured to correct a weight or mass measurement by the load cell 1 for the effects of a magnetic field or change in magnetic field detected by the magnetometer 33. For example, the error in the weight or mass measurement caused by different ambient or local magnetic fields or different changes in the ambient or local magnetic fields may have been characterised in advance, such that a measured ambient or local magnetic field or change in the ambient or local magnetic field can be converted into a corresponding error in the weight or mass measurement. This conversion may be performed using an equation, or using a table or graph that stores values of the magnetic field or change in magnetic field and values of the corresponding error in the weight or mass measurement, for example. The weight or mass measurement can then be corrected based on the determined error, for example by subtracting or adding the determined error to the weight or mass measurement.

Such a correction of the weight or mass measurement may only be carried out if it is determined that the ambient or local magnetic field has changed by more than a predetermined amount relative to a predetermined value, for example a value of the ambient or local magnetic field measured when the load cell 1 was last or most recently calibrated.

The error in the weight or mass measurement by the load cell 1 caused by ambient or local magnetic fields or changes in the ambient or local magnetic fields may have been characterised in advance by performing a weight or mass measurement on a reference weight or mass for different applied ambient or local magnetic fields.

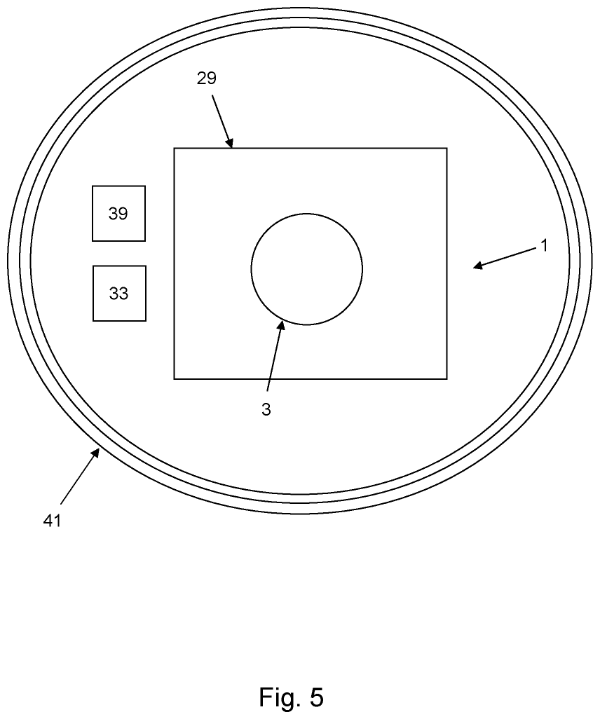

For example, a wire coil may be positioned around an outside of the load cell 1 for applying an ambient or local magnetic field in the vicinity of the load cell 1. A reference weight or mass having a known weight or mass may then be loaded on the load cell 1, and different measurements performed by the load cell 1 for different currents applied to the wire coil that generate different magnitudes of applied ambient or local magnetic fields in the vicinity of the load cell 1. The applied ambient or local magnetic field may be measured with a magnetometer, for example the magnetometer 33 described above. In this manner, a relationship can be determined between the magnitude of the applied ambient or local magnetic field and the error in the weight or mass measurement of the load cell 1. An apparatus for performing such a characterisation is illustrated in FIG. 5 for example, which illustrates a coil of wire 41 arranged around an outside of the load cell 1, for example the load cell 1 illustrated in FIG. 3 and described above, for applying an ambient or local magnetic field in the vicinity of the load cell when a current is applied to the coil of wire 41. The current through the coil of wire 41 can be changed to change the magnitude of the applied ambient or local magnetic field.

The characterisation method may comprise providing a first current to the coil of wire, for example 0.2 A, measuring the generated magnetic field in the vicinity of the load cell 1, and performing a measurement on the reference mass or weight using the load cell 1. The characterisation method may further comprise increasing the current in steps, for example of 0.2 A increments, and measuring the magnetic field and performing a measurement on the reference mass or weight for each current provided to the coil of wire.

There may be a linear relationship between the magnitude of the applied ambient or local magnetic field and the error in the weight or mass measurement. Therefore, the characterisation may comprise determining the equation of this linear relationship. More generally, the characterisation may comprise determining an equation of a relationship between the magnitude or change in magnitude of the applied ambient or local magnetic field and the error in the weight or mass measurement.

Such an equation can then be used to determine the error in the weight or mass measurement of the load cell 1 that would be caused by a specific magnitude or change in magnitude of the ambient or local magnetic field measured by the magnetometer 33.

The characterisation method may comprise determining a relationship or equation between the magnitude of the applied ambient or local magnetic field and the error in the weight or mass measurement for magnetic fields applied along each of three mutually perpendicular axes, for example x, y, and z. There may therefore be three such relationships or equations, or a relationship or equation into which the three different directional components of the magnetic field are input.

The coil 41 illustrated in FIG. 5 may apply a magnetic field along only a single direction, and the direction along which the magnetic field is applied may be changed by reorienting the coil 41 relative to the load cell 1, for example by rotating the coil by 90 degrees

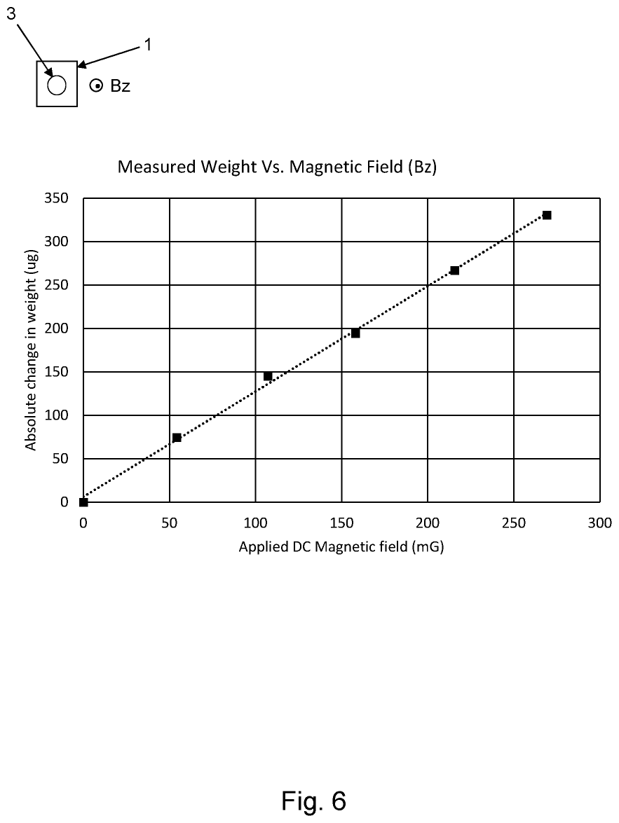

FIGS. 6 to 8 are experimental data illustrating errors in the output of a load cell caused by different magnitudes of magnetic field applied in the vicinity of the load cell. For example, the experimental data may be obtained using the arrangement illustrated in FIG. 5 and described above. The coil 41 was reorientated between each of FIGS. 6 to 8 to apply the magnetic field in each the mutually perpendicular x, y and z directions.

FIG. 6 shows the effects of different magnitudes of magnetic field in the Bz direction, which is vertically upwards perpendicular to the pan 3 of the load cell 1. As shown in FIG. 6, there is a linear relationship between the magnitude of the applied magnetic field in the Bz direction and the error in the mass measurement performed by the load cell 1.

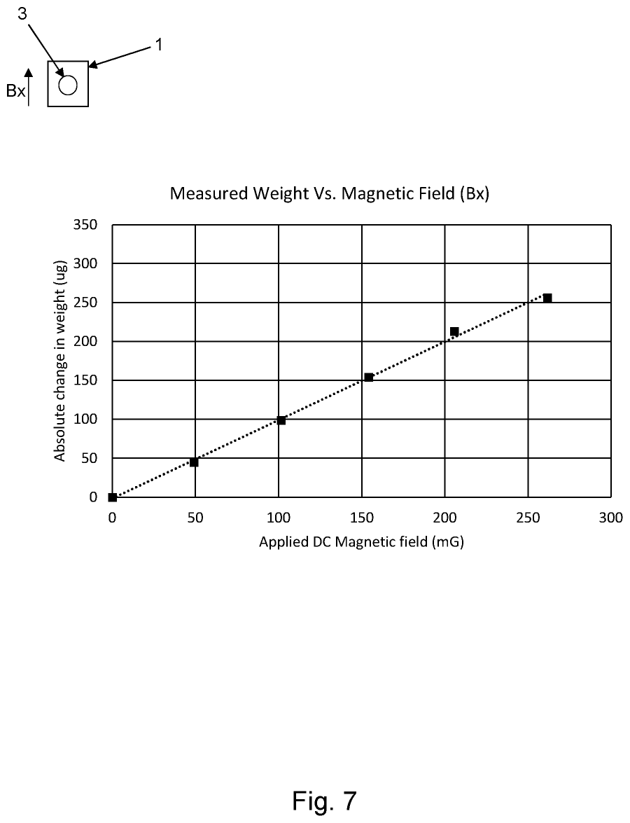

FIG. 7 shows the effects of different magnitudes of magnetic field in the Bx direction, which is a first horizontal direction parallel to the pan 3 of the load cell 1. As shown in FIG. 7, there is a linear relationship between the magnitude of the applied magnetic field in the Bx direction and the error in the mass measurement performed by the load cell 1.

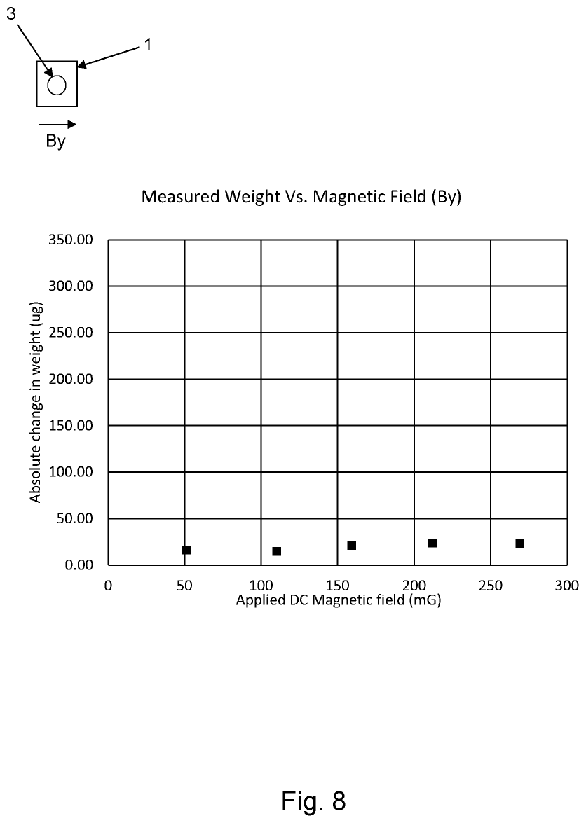

FIG. 8 shows the effects of different magnitudes of magnetic field in the By direction, which is a second horizontal direction parallel to the pan 3 of the load cell 1. As shown in FIG. 7, the load cell 1 is essentially not sensitive to magnetic fields in the By direction, or is significantly less sensitive to magnetic fields in the By direction than the Bx and Bz directions.

As shown in FIGS. 6 to 8, the load cell in this embodiment is more sensitive to magnetic fields in the Bz and Bx directions, and less sensitive to magnetic fields in the By direction.

Of course, other load cells may have the same sensitivity to different directions of magnetic field, or sensitivities that are different but in a different manner to those illustrated in FIGS. 6 to 8. This will depend on the specifics of the load cell, and can be characterised in advance in the manner described above.

Characterisation of the load cell 1 may therefore lead to three different equations or relationships that relate the magnitude of the magnetic field to the error in the mass or weight measurement for each of the three perpendicular axes Bx, By and Bz. By measuring the magnitude of the magnetic field in each of these directions in the vicinity of the load cell 1 when the load cell 1 is used to perform a measurement, a correction value for correcting the measurement can be calculated as the sum of the errors for each of these three directions. Alternatively, the magnetic field may be measured as a vector quantity and converted into a single error using a single equation or relationship, for example.

In order to reduce the ambient or local magnetic field in the vicinity of the load cell 1, it is possible to provide a magnetic shield around some or all of the load cell 1. Such a magnetic shield may take the form of a housing or enclosure or chamber around the load cell 1 that is made from a material having high magnetic permeability, such as a ferromagnetic material such as Mu metal. However, the error in the measurement of the load cell 1 may still be significant even with such magnetic shielding if there is a high external magnetic field. Therefore, the present invention may be beneficial even when such magnetic shielding is provided.

Alternatively, or in addition, the apparatus may be configured to actively cancel the ambient or local magnetic field in the vicinity of the load cell 1 based on the output of the magnetometer 33, and/or based on the identification or detection of the event.

For example, the apparatus may comprise one or more magnetic field generators for generating a magnetic field in the vicinity of the load cell, and the apparatus (for example the controller or processor 39) may be configured to control the one or more magnetic field generators to reduce or counteract or cancel out the ambient or local magnetic field detected by the magnetometer. For example, the one or more magnetic field generators may be controlled to reduce a magnitude of an output of the magnetometer to be below a predetermined threshold value, indicating that the ambient or local magnetic field in the vicinity of the load cell is below a predetermined threshold value.

The one or more magnetic field generators may be configured to generate a constant or uniform or DC magnetic field in order to reduce or counteract or cancel out a constant or uniform or DC ambient or local magnetic field detected by the magnetometer 33.

Therefore, the one or more magnetic field generators may be configured to counteract uniform ambient or local magnetic fields, or low frequency ambient or local magnetic fields. As discussed above, high frequency changes to the ambient or local magnetic fields may have less of an effect on the measurement output of the load cell 1, and therefore an acceptable accuracy may be achievable without cancelling out or reducing such high frequency changes in the magnetic field.

As mentioned above, spikes in the magnetic field having a duration of 1 or 2 seconds may be corrected for by the load cell waiting for a stable measurement value before outputting a measurement value. Therefore, spike in the magnetic field having this duration or less may have less of an effect on the measurement output of the load cell 1.

In any of the embodiments described above more than one magnetometer may be provided, for measuring the magnetic field in more than one location in the vicinity of the load cell 1.

In one embodiment a first magnetometer may be provided on a first side of the load cell and a second magnetometer may be provided on an opposite second side of the load cell. Measurement outputs from the first and second magnetometers may be used to calculate a gradient of the magnetic field between the first and second magnetometers and across the load cell. This gradient may be used to calculate or estimate or predict the magnetic field at the location of the load cell, or at a specific location within the load cell, for example a specific location of the electromagnetic force compensation mechanism.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

1. An apparatus for measuring the mass and/or the change in mass of an object, comprising:
a load cell; and
a magnetic field sensor.

2. The apparatus according to claim 1, wherein the magnetic field sensor comprises a magnetometer.

3. The apparatus according to claim 1, wherein the apparatus is configured to periodically or continuously monitor an output of the magnetic field sensor.

4. The apparatus according to claim 1, wherein the apparatus is configured to identify or detect an event based on an output of the magnetic field sensor.

5. The apparatus according to claim 4, wherein the event comprises a change in the output of the magnetic field sensor that is greater than or equal to a predetermined value.

6. The apparatus according to claim 1, wherein the apparatus is configured to determine when a change in an output of the magnetic field sensor is greater than or equal to a predetermined value.

7. The apparatus according to claim 1, wherein the apparatus is configured to perform an action or control an operation of the apparatus based on an output of the magnetic field sensor.

8. The apparatus according to claim 1, wherein the apparatus is configured to trigger or perform or schedule a calibration of the load cell based on an output of the magnetic field sensor.

9. The apparatus according to claim 8, wherein the apparatus is configured to trigger or perform or schedule the calibration of the load cell when the apparatus determines that a change in an output of the magnetic field sensor is greater than or equal to a predetermined value.

10. The apparatus according to claim 1, wherein the apparatus is configured to determine an error in a measurement performed by the load cell based on a measurement output of the magnetic field sensor.

11. The apparatus according to claim 10, wherein the apparatus is configured to determine the error in the measurement performed by the load cell based on the measurement output of the magnetic field sensor using a predetermined relationship, equation or table.

12. The apparatus according to claim 10, wherein the magnetic field sensor is configured to measure a magnetic field in each of three perpendicular axes, and wherein the apparatus is configured to determine the error in the measurement performed by the load cell based on the measured magnetic field in each of the three perpendicular axes.

13. The apparatus according to claim 12, wherein the apparatus is configured to determine the error in the measurement performed by the load cell based on the measured magnetic field in each of the three perpendicular axes using a respective predetermined relationship, equation or table for each of the three perpendicular axes.

14. The apparatus according to claim 10, wherein the apparatus is configured to correct the measurement performed by the load cell based on the determined error in the measurement.

15. The apparatus according to claim 1, wherein the measurement performed by the load cell comprises measurement of a weight or mass of an object loaded onto the load cell.

16. The apparatus according to claim 1, wherein the load cell is an electromagnetic force compensation load cell.

17. The apparatus according to claim 1, wherein the load cell comprises an electromagnetic force compensation mechanism.

18. The apparatus according to claim 1, wherein the apparatus is configured to calculate the mass and/or the change in mass of an object loaded onto the load cell based at least on a measurement performed by the load cell.

19. The apparatus according to claim 1, wherein the apparatus comprises a measurement chamber in which the load cell is housed, and wherein the magnetic field sensor is located inside the measurement chamber.

20. The apparatus according to claim 1, wherein the load cell comprises a housing, and wherein the magnetic field sensor is located outside the housing.

21. The apparatus according to claim 1, wherein the magnetic field sensor is arranged within 100 cm, or within 50 cm, or within 20 cm, or within 10 cm, of the load cell.

22. The apparatus according to claim 1, wherein the apparatus comprises one or more magnetic field generators, and wherein the apparatus is configured to control the one or more magnetic field generators based on an output of the magnetic field sensor.

23. The apparatus according to claim 1, wherein the apparatus is configured to control the one or more magnetic field generators to reduce an output of the magnetic field sensor.

24. The apparatus according to claim 1, wherein the apparatus is for measuring the mass and/or the change in mass of a semiconductor wafer.

25. The apparatus according to claim 1, wherein the apparatus further comprises a magnetic shield that is configured to at least partially magnetically shield at least part of the load cell.

26. The apparatus according to claim 25, wherein the magnetic field sensor is inside of the magnetic shield.

27. The apparatus according to claim 1, wherein the apparatus comprises a plurality of magnetic field sensors, each of which is configured to measure a magnetic field in a respective predetermined direction.

28. The apparatus according to claim 1, wherein the apparatus comprises a plurality of magnetic field sensors, and wherein the apparatus is configured to calculate a magnetic field at a position between two of the plurality of magnetic field sensors based on outputs of the two magnetic field sensors.

29. A method performed by the apparatus according to claim 1, the method comprising:
measuring a magnetic field with the magnetic field sensor; and
performing an action or controlling an operation of the apparatus based on the measurement of the magnetic field.

30. A method comprising:
loading an object on a load cell;
exposing the load cell to a first magnetic field;
performing a first measurement on the object with the load cell while the load cell is exposed to the first magnetic field;
exposing the load cell to a second magnetic field different to the first magnetic field; and
performing a second measurement on the object with the load cell while the load cell is exposed to the second magnetic field.

31. The method according to claim 30, wherein the method comprises determining a sensitivity of the load cell to a magnetic field based on at least the first measurement and the second measurement.

32. The method according to claim 30, wherein the method comprises determining a relationship, equation or table that relates the magnetic field to an error in a measurement performed by the load cell when the load cell is exposed to that magnetic field based on at least the first measurement and the second measurement.

33. The method according to claim 30, wherein the method comprises:
sequentially exposing the load cell to three or more different magnetic fields; and
performing a measurement of the object while the load cell is exposed to each of the three or more different magnetic fields.
